(19) United States
(12) Patent Application Publication
(10) Pub. No.: US 2021/0392776 A1
(43) Pub. Date: Dec. 16, 2021

(54) SELECTIVE REMOVAL OF FLUID FROM 2-PHASE HEAT TRANSFER THERMAL MANAGEMENT SYSTEMS

(71) Applicant: 3M INNOVATIVE PROPERTIES COMPANY, St. Paul, MN (US)

(72) Inventors: Phillip E. Tuma, Fairbault, MN (US); Jinsheng Zhou, Woodbury, MN (US)

(21) Appl. No.: 17/287,589

(22) PCT Filed: Oct. 18, 2019
(86) PCT No.: PCT/IB2019/058926

§ 371 Date: Apr. 22, 2021

Related U.S. Application Data
(60) Provisional application No. 62/748,585, filed on Oct. 22, 2018.

(51) Int. Cl. H05K 7/20

(52) U.S. Cl. CPC H05K 7/203; H05K 7/20318

(57) ABSTRACT

An immersion cooling system includes a housing having an interior space; a heat-generating component disposed within the interior space; and a working fluid liquid disposed within the interior space such that the heat-generating component is in contact with a liquid phase of the working fluid. The immersion system further includes a device configured to selectively remove a fluid from within the housing. The working fluid includes a halogenated material.

### FIELD

The present disclosure relates to systems and methods for selectively removing fluids from 2-phase thermal management systems

### BACKGROUND

Various systems for managing the presence of water in immersion cooling systems are described in, for example, Tuma, P. E., “A Comparison of Passive 2-phase Immersion and Pumped Water Cooling for Cooling Datacom Equipment,” presentation IMAPs ATW on Thermal Management, Palo Alto, Calif., USA, Nov. 7-9, 2011; and Tuma, P. E., “Design Considerations Relating to Non-Thermal Aspects of Passive 2-Phase Immersion Cooling,” to be published, Proc. 27th IEEE Semi-Therm Symposium, San Jose, Calif., USA, Mar. 20-24, 2011.

### SUMMARY

In some embodiments, an immersion cooling system is provided. The immersion cooling system includes a housing having an interior space; a heat-generating component disposed within the interior space; and a working fluid liquid disposed within the interior space such that the heat-generating component is in contact with the working fluid liquid. The working fluid includes a halogenated material. The immersion system further includes a device configured to selectively remove a fluid from within the housing.

The above summary of the present disclosure is not intended to describe each embodiment of the present disclosure. The details of one or more embodiments of the disclosure are also set forth in the description below. Other features, objects, and advantages of the disclosure will be apparent from the description and from the claims.

### BRIEF DESCRIPTION OF THE FIGURES

FIG. 1 is a schematic of a two-phase immersion cooling system according to some embodiments of the present invention.

FIG. 2 is a graph of the relative humidity as a function of time of Example 1 and Comparative Example CE1.

### DETAILED DESCRIPTION

Large scale computer server systems can perform significant workloads and generate a large amount of heat during their operation. A significant portion of the heat is generated by the operation of these server systems. Due in part to the large amount of heat generated, these servers are typically rack mounted and air-cooled via internal fans and/or fans attached to the back of the rack or elsewhere within the server ecosystem. As the need for access to greater and greater processing and storage resources continues to expand, the density of server systems (i.e., the amount of processing power and/or storage placed on a single server, the number of servers placed in a single rack, and/or the number of servers and or racks deployed on a single server farm), continue to increase. With the desire for increasing processing or storage density in these server systems, the thermal challenges that result remain a significant obstacle. Conventional cooling systems (e.g., fan based) require large amounts of power, and the cost of power required to drive such systems increases exponentially with the increase in server densities. Consequently, there exists a need for efficient, low power usage system for cooling the servers, while allowing for the desired increased processing and/or storage densities of the server systems.

Two-phase immersion cooling is an emerging cooling technology for the high-performance server computing market which relies on the heat absorbed in the process of vaporizing a liquid (the cooling fluid) to a gas (i.e., the heat of vaporization). The working fluids used in this application must meet certain requirements to be viable in the application. For example, the boiling temperature during operation should be in a range between for example 30° C.-75° C. Generally, this range accommodates maintaining the server components at a sufficiently cool temperature while allowing heat to be dissipated efficiently to an ultimate heat sink (e.g., outside air). The working fluid must be inert so that it is compatible with the materials of construction and the electrical components. Certain perfluorinated and partially fluorinated materials meet these requirements.

In a typical two-phase immersion cooling system, servers are submerged in a bath of working fluid (having a boiling temperature T_{b}) that is sealed and maintained at or near atmospheric pressure. A vapor condenser integrated into the tank is cooled by water at temperature T_{w}. During operation, after steady reflux is established, the working fluid vapor generated by the boiling working fluid forms a discrete vapor level as it is condensed back into the liquid state. Above this layer is the “headspace,” a mixture of a non-condensable gas (typically air), water vapor, and the working fluid vapor which is at a temperature somewhere between T_{w} and the temperature of ambient air outside the tank, T_{amb}. These 3 distinct phases (liquid, vapor, and headspace) occupy volumes within the tank. During operation, the boiling process sparges (pushes up) all the water to the headspace volume. As a practical matter, liquid water will always form in the headspace at least during startup of the system.

The presence of liquid water in the cooling system (particularly in the headspace) is undesirable for several reasons. First, it contributes to corrosion of metal components in the headspace of the tank. Second, if boiling of the liquid is vigorous, water droplets may fall through the liquid and attach to sensitive electronic components causing short circuits. Lastly, for certain fluoromaterials, water may react with the materials to form acids.

Currently, desiccants are employed in two-phase immersion cooling systems to capture and remove liquid water present in the system. However, use of desiccants is undesirable at least because they require ongoing maintenance by the user (which, if overlooked, can cause system failure). Additionally, use of some desiccants can concentrate water in a manner that results in undesirable reactions for working fluids capable of reacting with water. Still further, desiccants often shed particulates that can contaminate systems.

Therefore, there continues to be a need for maintenance free and desiccant free systems and methods for removal of water from two-phase immersion cooling systems.

As used herein, “fluoro-” (for example, in reference to a group or moiety, such as in the case of “fluoroalkylene” or “fluoroalkyl” or “fluorocarbon”) or “fluorinated” means (i) partially fluorinated such that there is at least one carbon-bonded hydrogen atom, or (ii) perfluorinated.

As used herein, “perfluoro-” (for example, in reference to a group or moiety, such as in the case of “perfluoroalkylene” or “perfluoroalkyl” or “perfluorocarbon”) or “perfluorinated” means completely fluorinated such that, except as may be otherwise indicated, any carbon-bonded hydrogens are replaced by fluorine atoms.

As used herein, “halogenated material” means an organic compound that is at least partially halogenated (up to completely halogenated) such that there is at least one carbon-bonded halogen atom.

As used herein, “selective removal” refers to at least partial removal (up to total removal) of one or more particular fluid components (but less than all fluid components) from a sealed volume that includes two or more fluid components.

As used herein, “fluid” refers to the liquid phase and/or the vapor phase.

As used herein, the singular forms “a”, “an”, and “the” include plural referents unless the content clearly dictates otherwise. As used in this specification and the appended embodiments, the term “or” is generally employed in its sense including “and/or” unless the content clearly dictates otherwise.

As used herein, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

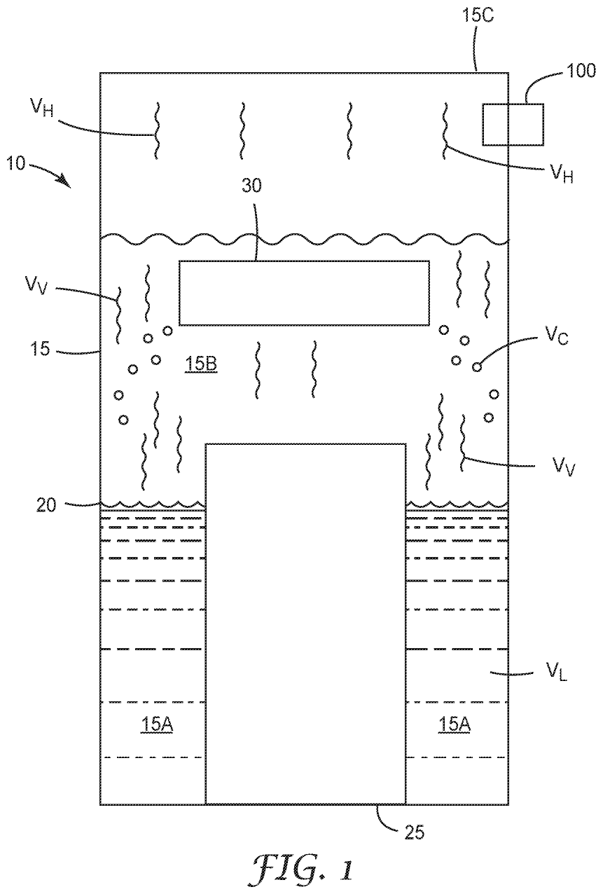

Generally, the present disclosure is directed to immersion cooling systems that provide for maintenance free and desiccant free removal of water from the system. In some embodiments, the immersion cooling systems may operate as two-phase vaporization-condensation systems for cooling one or more heat generating components. As shown in FIG. 1, in some embodiments, a two-phase immersion cooling system 10 may include a housing 15 having an interior space. Within a lower volume 15A of the interior space, a liquid phase V_{L} of a working fluid having an upper liquid surface 20 (i.e., the topmost level of the liquid phase V_{L}) may be disposed. The interior space may also include an upper volume 15B extending from the liquid surface 20 to an upper wall 15C of the housing 15. During steady state operation of the system 10, the upper volume 15B may include a vapor phase V_{V} of the working liquid (generated by the boiling working fluid and forming a discrete phase as it is condensed back into the liquid state) and a headspace phase V_{H} including a mixture of air and vapor, which is disposed above the vapor phase V_{V}.

In some embodiments, a heat generating component 25 may be disposed within the interior space such that it is at least partially immersed (and up to fully immersed) in the liquid phase V_{L} of the working fluid. That is, while heat generating component 25 is illustrated as being only partially submerged below the upper liquid surface 20, in some embodiments, the heat generating component 25 may be fully submerged below the liquid surface 20. In some embodiments, the heat generating components may include one or more electronic devices, such as computing servers.

In various embodiments, a heat exchanger 30 (e.g., a condenser) may be disposed within the upper volume 15B. Generally, the heat exchanger 30 may be configured such that it is able to condense the vapor phase V_{V} of the working fluid that is generated as a result of the heat that is produced by the heat generating element 25. For example, the heat exchanger 30 may have an external surface that is maintained at a temperature that is lower than the condensation temperature of the vapor phase V_{V} of the working fluid. In this regard, at the heat exchanger 30, a rising vapor phase V_{V} of the working fluid may be condensed back to liquid phase or condensate V_{C} by releasing latent heat to the heat exchanger 30 as the rising vapor phase V_{V} comes into contact with the heat exchanger 30. The resulting condensate V_{C} may then be returned back to the liquid phase V_{L} disposed in the lower volume of 15A.

In some embodiments, the working fluid may be or include one or more halogenated fluids (e.g., fluorinated or chlorinated). For example, the working fluid may be a fluorinated organic fluid. Suitable fluorinated organic fluids may include hydrofluoroethers, fluoroketones (or perfluoroketones), hydrofluoroolefins, perfluorocarbons (e.g., perfluorohexane), perfluoromethyl morpholine, or combinations thereof.

In some embodiments, in addition to the halogenated fluids, the working fluids may include (individually or in any combination): ethers, alkanes, perfluoroalkenes, alkenes, haloalkenes, perfluorocarbons, perfluorinated tertiary amines, perfluoroethers, cycloalkanes, esters, perfluoroketones, ketones, oxiranes, aromatics, siloxanes, hydrochlorocarbons, hydrochlorofluorocarbons, hydrofluorocarbons, hydrofluoroolefins, hydrochloroolefins, hydrochlorofluoroolefins, hydrofluoroethers, or mixtures thereof based on the total weight of the working fluid; or alkanes, perfluoroalkenes, haloalkenes, perfluorocarbons, perfluorinated tertiary amines, perfluoroethers, cycloalkanes, perfluoroketones, aromatics, siloxanes, hydrochlorocarbons, hydrochlorofluorocarbons, hydrofluorocarbons, hydrofluoroolefins, hydrochlorofluoroolefins, hydrofluoroethers, or mixtures thereof, based on the total weight of the working fluid. Such additional components can be chosen to modify or enhance the properties of a composition for a particular use.

In some embodiments, the working fluids of the present disclosure may have a boiling point during operation (e.g., pressures of between 0.9 atm and 1.1 atm or 0.5 atm and 1.5 atm) of between 30-75° C., or 35-75° C., 40-75° C., or 45-75° C. In some embodiments, the working fluids of the present invention may have a boiling point during operation of greater than 40° C., or greater than 50° C., or greater than 60° C., greater than 70° C., or greater than 75° C.

In some embodiments, the working fluids of the present disclosure may have dielectric constants that are less than 4.0, less than 3.2, less than 2.3, less than 2.2, less than 2.1, less than 2.0, or less than 1.9, as measured in accordance with ASTM D150 at room temperature.

In some embodiments, the working fluids of the present disclosure may be hydrophobic, relatively chemically unreactive, and thermally stable. The working fluids may have a low environmental impact. In this regard, the working fluids of the present disclosure may have a zero, or near zero, ozone depletion potential (ODP) and a global warming potential (GWP, 100 yr ITH) of less than 500, 300, 200, 100 or less than 10.

In some embodiments, the system 10 may further include a device 100 configured to selectively remove a fluid (e.g., water) from within housing 15. More specifically, the device 100 may be configured to permit removal of a fluid from within the housing 15, but not permit (or permit to a much lesser extent) the removal of the working fluid.

In some embodiments, the device 100 may include (or be formed of) a pervaporative membrane. As used herein, the phrase “pervaporative membrane” refers to a device or article that allows for the separation of mixtures of fluids (e.g., organic fluids and water (including water vapor), or fluorinated fluids and water (including water vapor)) by (i) pervaporation with a first membrane surface contacting a liquid mixture, the membrane then selectively permeating through one or more liquid components via the first membrane surface; and then vaporizing the permeated liquid component(s) at a second membrane surface; or (ii) pervaporation with a first membrane surface contacting a vapor mixture, the membrane then selectively permeating through one or more vapor components via the first membrane surface, and then vaporizing the permeated vapor component(s) at a second membrane surface.

In some embodiments, the pervaporative membrane may be a hydrophilic membrane. Alternatively, hydrophobic membranes may be employed.

In some embodiments, the driving force for the transport of components through the pervaporative membranes of the present disclosure may be the chemical potential gradient and, more specifically, the partial vapor pressure gradient of the components in the interior space of the housing 15 relative to the ambient environment surrounding the immersion cooling system 10. In this regard, it was discovered that thermodynamic conditions allow the use of pervaporative venting of moisture through pervaporative membranes. Two-phase immersion systems are typically run at the highest temperature possible so that the heat that is removed from the system can be deposited to the ambient environment with minimal additional power for the dry cooler pumps and fan. Therefore, it is most often the case that the temperature of the condenser water and therefore the headspace V_{H} of the tank will be warmer than the ambient environment in which the immersion cooling system 10 is disposed. It follows that the saturation pressure of water in the headspace V_{H} will be higher than that outside the immersion cooling system 10. Since, as discussed above, diffusion of water across a pervaporative membrane is driven by the water partial pressure difference, it follows that there will always be potential for driving water out of an immersion cooling system (even if the ambient relative humidity is 100%). That is, with a pervaporative membrane present at equilibrium, the relative humidity in the headspace V_{H} will always be less than 100% so that water cannot liquefy. While the present disclosure is primarily directed to selectively remove water (liquid or vapor) from the system, it is to be appreciated the concepts of the present disclosure could be employed to, additionally or alternatively, remove other fluids from the system.

In some embodiments, the device 100 may be disposed within or coupled to the housing 15 (e.g., coupled to a sidewall of the housing 15). In some embodiments, the device 100 may be disposed within the housing 15 such that a first working side of the device 100 (e.g., a first major surface of the pervaporative membrane) is in fluid communication with the headspace V_{H} and a second working side of the device 100 (e.g., a second major surface of the pervaporative membrane) is in fluid communication with ambient environment surrounding the immersion cooling system 10.

In some embodiments, the present disclosure may be directed to methods for cooling electronic components. Generally, the methods may include at least partially immersing a heat generating component (e.g., a computer server) in the above discussed working fluid. The method may further include transferring heat from the heat generating component using the above-described working fluid. The method may further include selectively removing a fluid from a housing that contains the heat generating component and the working fluid using the above discussed device 100.

### Listing of Embodiments

1. A cooling system comprising:
   a housing having an interior space;
   a heat-generating component disposed within the interior space; and
   a working fluid disposed within the interior space such that the heat-generating component contacts a liquid phase of the working fluid; and
   a device configured to selectively remove a fluid from within the housing;
   wherein the working fluid comprises a halogenated material.
2. The cooling system of embodiment 1, wherein the device is configured to selectively remove water from within the housing.
2. The cooling system of embodiment 1, wherein the device is configured to selectively remove water vapor from within the housing.
3. The cooling system of any one of the previous embodiments, wherein the device comprises a pervaporative membrane.
4. The cooling system of any one of the previous embodiments, wherein the cooling system is configured such that in a steady state operating condition, (i) a liquid phase of the working fluid is disposed in a lower volume of the housing, (ii) a vapor phase of the working fluid is disposed above liquid phase, and (iii) a headspace phase comprising a non condensable gas, water vapor, and working fluid vapor is disposed above the vapor phase.
5. The cooling system of embodiment 4, wherein the device is disposed within the housing such that a first working side of the device is in fluid communication with the headspace phase and a second working side of the device is in fluid communication with an ambient environment surrounding the immersion cooling system.
6. The cooling system of any one of the previous embodiments, wherein the working fluid comprises a fluorinated material.
7. The cooling system of any one of the previous embodiments, wherein the working fluid has a boiling point at 1 atm of between 30 and 75° C.
8. The cooling system of any one of the previous embodiments, wherein the working fluid has a dielectric constant less than 2.5.
9. The cooling system of any one of the previous embodiments, wherein the heat-generating component comprises an electronic device.
10. The cooling system of embodiment 9, wherein the electronic device comprises a computing server.
11. The cooling system of embodiment 10, wherein the computing server operates at frequency of greater than 3 GHz.
12. The cooling system of embodiment 4, wherein the cooling system comprises a heat exchanger disposed within the system such that upon vaporization of the working fluid liquid, the vapor phase contacts the heat exchanger.

The operation of the present disclosure will be further described with regard to the following detailed examples. These examples are offered to further illustrate various embodiments and techniques. It should be understood, however, that many variations and modifications may be made while remaining within the scope of the present disclosure.

### EXAMPLES

Objects and advantages of this disclosure are further illustrated by the following comparative and illustrative examples. Unless otherwise noted, all parts, percentages, ratios, etc. in the examples and the rest of the specification are by weight, and all reagents used in the examples were obtained, or are available, from general chemical suppliers such as, for example, Sigma-Aldrich Corp., Saint Louis, Mo., US, or may be synthesized by conventional methods. The following abbreviations are used herein: cm³=cubic centimeters, wt %=percentage by weight, m/min=meters per minute, μm=micrometers (10⁻⁶ m), ° C.=degrees Celsius.

### Membrane Preparation Procedures

A 5 wt % coating solution was prepared from NAFION 1000EW in proton form (available from Chemours, Wilmington, Del., US) in a solvent mixture of 75 wt % ethanol and 25 wt % deionized water. The coating solution was applied to a porous polyacrylonitrile substrate (PA350, Nanostone Water, Oceanside, Calif., US) using a slot die in a pilot line. The line speed was set at 2.0 m/min. The solvent was evaporated in four temperature-controlled ovens (7.6 meters long) set to 40° C., 40° C., 60° C., and 70° C., respectively, which targeted a 1.0 μm thickness of dry NAFION coating film on top of the porous substrate.

### Immersion Cooling System Tank

An immersion cooling system as shown in FIG. 1 was constructed such that the approximate volumes of the 3 phases during operation were:
V_{L}=920 cm³
V_{V}=1750 cm³
V_{H}=750 cm³

For both Example 1 and Comparative Example CE1, the tank was charged with FLUORINERT FC-72 fluid (available from 3M Company, St. Paul, Minn., US) from the same container. For CE1, the top viewing window remained in place. For Example 1, a 135 cm² membrane, prepared as described above, was applied instead of the top viewing window. For each experiment, the liquid and vapor temperatures were monitored during startup along with the relative humidity near the top of the tank.

### Results

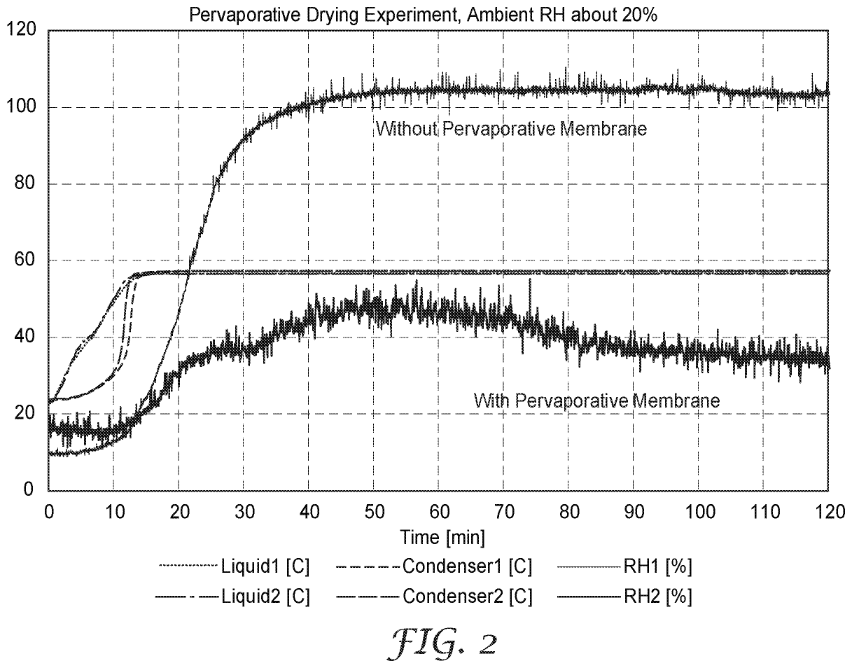

Results are provided in FIG. 2, which shows the relative humidity in the system as a function of system run time. For CE1, without the membrane, the relative humidity quickly reached 100% and water condensed on the window of the tank. For Example 1, with the membrane in place, relative humidity barely exceeded 50%.

Although specific embodiments have been illustrated and described herein for purposes of description of some embodiments, it will be appreciated by those of ordinary skill in the art that a wide variety of alternate and/or equivalent implementations may be substituted for the specific embodiments shown and described without departing from the scope of the present disclosure.

1. A cooling system comprising:
a housing having an interior space;
a heat-generating component disposed within the interior space; and
a working fluid disposed within the interior space such that the heat-generating component contacts a liquid phase of the working fluid; and
a device configured to selectively remove a fluid from within the housing;
wherein the working fluid comprises a halogenated material.

2. The cooling system of claim 1, wherein the device is configured to selectively remove water from within the housing.

3. The cooling system of claim 1, wherein the device comprises a pervaporative membrane.

4. The cooling system of claim 1, wherein the cooling system is configured such that in a steady state operating condition, (i) a liquid phase of the working fluid is disposed in a lower volume of the housing, (ii) a vapor phase of the working fluid is disposed above liquid phase, and (iii) a headspace phase comprising a non condensable gas, water vapor, and working fluid vapor is disposed above the vapor phase.

5. The cooling system of claim 4, wherein the device is disposed within the housing such that a first working side of the device is in fluid communication with the headspace phase and a second working side of the device is in fluid communication with an ambient environment surrounding the immersion cooling system.

6. The cooling system of claim 1, wherein the working fluid comprises a fluorinated material.

7. The cooling system of claim 1, wherein the working fluid has a boiling point at 1 atm of between 30 and 75° C.

8. The cooling system of claim 1, wherein the working fluid has a dielectric constant less than 2.5.

9. The cooling system of claim 1, wherein the heat-generating component comprises an electronic device.

10. The cooling system of claim 9, wherein the electronic device comprises a computing server.

11. The cooling system of claim 10, wherein the computing server operates at frequency of greater than 3 GHz.

12. The cooling system of claim 4, wherein the cooling system comprises a heat exchanger disposed within the system such that upon vaporization of the working fluid liquid, the vapor phase contacts the heat exchanger.
